(19) United States
(12) Patent Application Publication
(10) Pub. No.: US 2015/0024517 A1
(43) Pub. Date: Jan. 22, 2015

(54) PLASMA ETCHER CHUCK BAND

(71) Applicant: Texas Instruments Incorporated, Dallas, TX (US)

(72) Inventor: John Christopher SHRINER, Allen, TX (US)

(21) Appl. No.: 14/328,814

(22) Filed: Jul. 11, 2014

Related U.S. Application Data
(60) Provisional application No. 61/856,094, filed on Jul. 19, 2013.

(51) Int. Cl. H01L 21/66; H01L 21/67; H01L 21/687; H01L 21/3065

(52) U.S. Cl. CPC H01L 22/12; H01L 21/3065; H01L 21/67069; H01L 21/687
USPC 438/9; 156/345.51; 156/345.52

(57) ABSTRACT

A plasma etch tool includes a wafer chuck with a chuck base and at least one functional component layer attached to the chuck base. A perimeter of the functional component layer has a polymer material permanently attached to it that extends to within 2 millimeters of a top surface of the chuck. The top surface of the wafer chuck contacts a bottom surface of a semiconductor wafer during an etch process for forming an integrated circuit. The polymer material is protected from an etch ambient by a plasma etcher chuck band installed around the perimeter of the functional component layer, extending over a portion of the chuck base. An integrated circuit may be formed by installing the plasma etcher chuck band on the chuck of the plasma etch tool, and subsequently performing an etch process in the plasma etch tool on a semiconductor wafer containing the partially formed integrated circuit.

### FIELD OF THE INVENTION

This invention relates to the field of process equipment for integrated circuits. More particularly, this invention relates to plasma equipment for integrated circuits.

### BACKGROUND OF THE INVENTION

A plasma etch tool for fabricating integrated circuits may include a chuck for supporting the wafer which has one or more functional component layers, such as a wafer heater and/or an electrostatic platen attached to the chuck base. The chuck may include a partially exposed polymer material used, for example, to seal edges of the functional component layers or to attach the functional component layers to the chuck base. The polymer material may be susceptible to degradation from the etch environment, undesirably adding to equipment maintenance costs.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

A plasma etch tool includes a wafer chuck with a chuck base and at least one functional component layer over the chuck base. A polymer material is permanently attached to the functional component layer and extends to a perimeter of the functional component layer so as to be exposed at the perimeter of the functional component layer. The polymer material is protected from an etch ambient by a plasma etcher chuck band installed around the perimeter of the functional component layer, covering the exposed polymer material, and extending over a portion of the chuck base.

An integrated circuit may be formed by installing the plasma etcher chuck band on the chuck of the plasma etch tool, and subsequently performing an etch process in the plasma etch tool on a semiconductor wafer containing the partially formed integrated circuit.

### DESCRIPTION OF THE VIEWS OF THE DRAWING

FIG. 1 is a cross section of a portion of an exemplary plasma etch tool, showing a plasma etcher chuck band installed on a chuck at room temperature.

FIG. 2 is a cross section of the plasma etch tool during an etch process of a fabrication process sequence for an integrated circuit.

FIG. 3 is a cross section of the plasma etch tool during the etch process, depicting a worst case of misalignment of the insulator ring and the semiconductor wafer.

FIG. 4 is a cross section of the plasma etch tool during a chamber cleaning process.

FIG. 5 is a cross section of the plasma etch tool during a maintenance process.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

A plasma etch tool includes a wafer chuck with a chuck base and at least one functional component layer, for example a wafer heater, an electrostatic platen or a vacuum platen, attached to the chuck base. A perimeter of the functional component layer has a polymer material, for example epoxy, permanently attached to it that extends to within 2 millimeters of a top surface of the wafer chuck. The top surface of the wafer chuck contacts a bottom surface of a semiconductor wafer during an etch process for forming an integrated circuit. The polymer material is protected from an etch ambient in the plasma etch tool by a plasma etcher chuck band installed around the perimeter of the functional component layer, extending over a portion of the chuck base.

An integrated circuit may be formed by installing the plasma etcher chuck band on the chuck of the plasma etch tool, and subsequently performing an etch process in the plasma etch tool on a semiconductor wafer containing the partially formed integrated circuit. The plasma etcher chuck band may be visually inspected for etch damage and replaced before protection of the polymer material around the functional component layer is compromised.

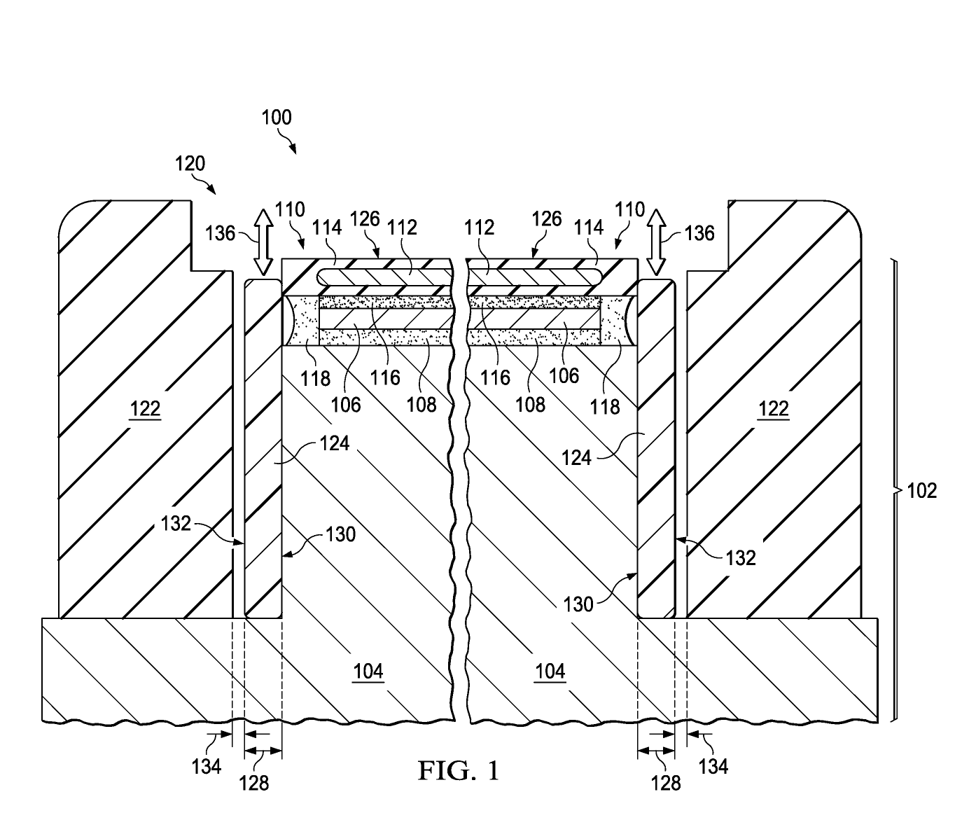

FIG. 1 is a cross section of a portion of an exemplary plasma etch tool, showing a plasma etcher chuck band installed on a chuck at room temperature. The plasma etch tool 100 includes a wafer chuck 102 which has a chuck base 104. The chuck base 104 may be formed, for example, of anodized aluminum. One or more functional component layers are disposed over the chuck base 104. In the instant example, a wafer heater 106 is attached to the chuck base 104 by a first adhesive layer 108. An electrostatic platen 110, which includes a high voltage electrode 112 surrounded by a ceramic insulator 114, is attached to the wafer heater 106 by a second adhesive layer 116. A polymer material 118 is permanently attached to the electrostatic platen 110, wafer heater 106, and chuck base 104. The polymer material 118 extends from an end of the wafer heater 106 to a perimeter of the electrostatic platen 110, where the polymer material 118 is exposed. The polymer material 118 may include, for example, epoxy. The polymer material 118 may isolate the first adhesive layer 108 and the second adhesive layer 116 from an etch region 120 of the plasma etch tool 100. An insulator ring 122, for example a quartz ring 122, is disposed around the wafer heater 106 and the electrostatic platen 110, and may rest on a shoulder of the chuck base 104.

A plasma etcher chuck band 124 is disposed between the chuck base 104 and the insulator ring 122, unattached to the wafer chuck 102, extending above the polymer material 118, for example to within 2 millimeters of a top surface 126 of the wafer chuck 102. The plasma etcher chuck band 124 may extend above the polymer material 118 at least 0.5 millimeters. The plasma etcher chuck band 124 is formed of an elastic polymer such as a perfluorinated polymer. A thickness 128 of the plasma etcher chuck band 124 may be 1 millimeter to 3 millimeters. At room temperature, that is, 20° C. to 25° C., an inner surface 130 of the plasma etcher chuck band 124 contacts the wafer chuck 102 all along the plasma etcher chuck band 124. The plasma etcher chuck band 124 may be installed at room temperature by stretching the plasma etcher chuck band 124 by hand and slipping it over the functional component layers, that is the electrostatic platen 110 and the wafer heater 106 and onto the chuck base 104. At room temperature, an outer surface 132 of the plasma etcher chuck band 124 is separated from the insulator ring 122 by a lateral separation 134 of 0.5 millimeters to 1.5 millimeters. The lateral separation 134 may advantageously be selected to facilitate installation and removal of the plasma etcher chuck band 124, as indicated by installation/removal arrows 136.

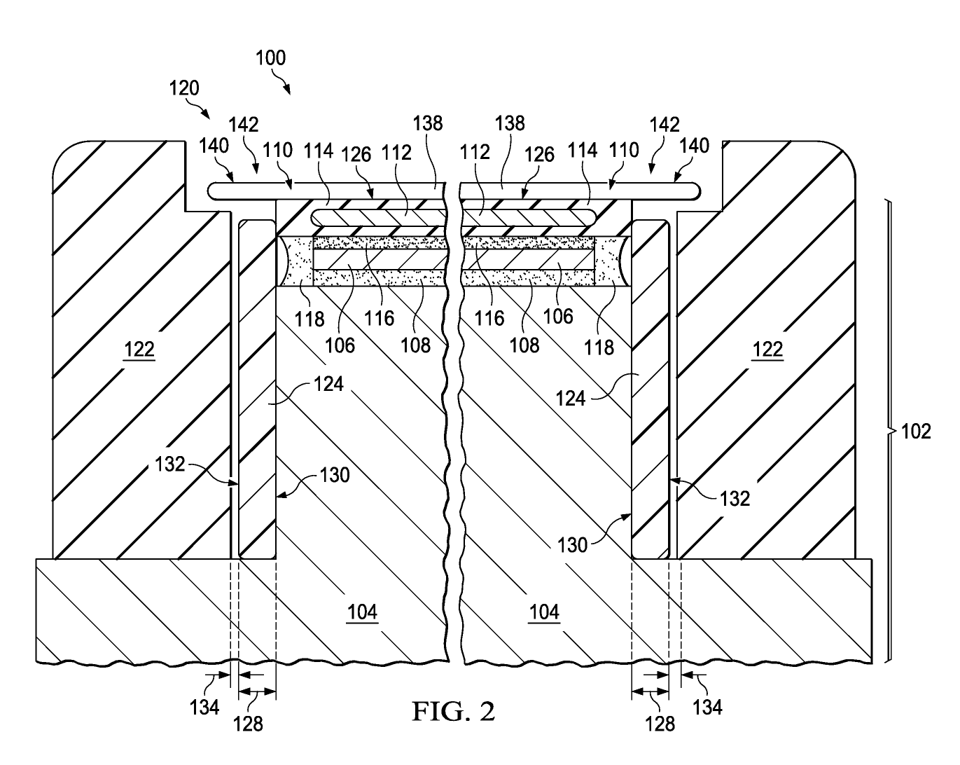

FIG. 2 is a cross section of the plasma etch tool 100 during an etch process of a fabrication process sequence for an integrated circuit. A semiconductor wafer 138 is placed on the wafer chuck 102 so that a top surface 140 of the semiconductor wafer 138 is exposed to the etch region 120 of the plasma etch tool 100. The integrated circuit 142 is located at the top surface 140 of the semiconductor wafer 138. The semiconductor wafer 138 overhangs the outer surface 132 of the plasma etcher chuck band 124. During the etch process, the wafer chuck 102 is heated to a process temperature of 50° C. to 200° C. For example, in a gate etch process, the wafer chuck 102 may heated to a process temperature of 55° C. to 70° C. When the wafer chuck 102 is heated to the process temperature, the chuck base 104 expands so that the inner surface 130 of the plasma etcher chuck band 124 seals against the wafer chuck 102 all along the plasma etcher chuck band 124, causing the polymer material 118 to be isolated from the etch region 120 by the plasma etcher chuck band 124. The lateral separation 134 between the outer surface 132 of the plasma etcher chuck band 124 and the insulator ring 122 is reduced. in one version of the instant example, the outer surface 132 of the plasma etcher chuck band 124 may not contact the insulator ring 122 all along the plasma etcher chuck band 124, advantageously reducing a risk of cracking the insulator ring 122. Reactant gases are introduced into the etch region 120 and radio-frequency (RF) power is applied to the etch region 120 to form a plasma of the reactant gases, so that etching occurs at the top surface 140 of the semiconductor wafer 138.

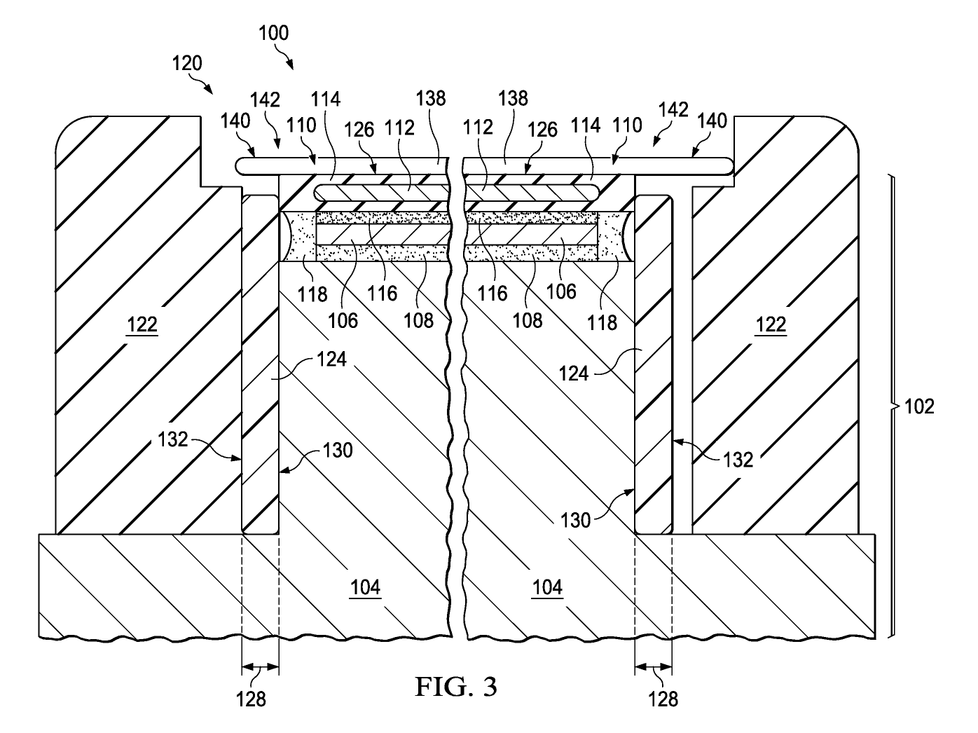

FIG. 3 is a cross section of the plasma etch tool 100 during the etch process, depicting a worst case of misalignment of the insulator ring 122 and the semiconductor wafer 138. The insulator ring 122 is moved laterally to the right, from its position in FIG. 2, so that the insulator ring 122 contacts the plasma etcher chuck band 124 at the left side of the wafer chuck 102. The semiconductor wafer 138 is also moved laterally to the right to contact the insulator ring 122 at the right side of the wafer chuck 102. The thickness 128 of the plasma etcher chuck band 124 may be selected so that in such a condition of worst case misalignment, the semiconductor wafer 138 overlaps the outer surface 132 of the plasma etcher chuck band 124 all around the plasma etcher chuck band 124, advantageously reducing damage to the plasma etcher chuck band 124 from etchants in the etch region 120.

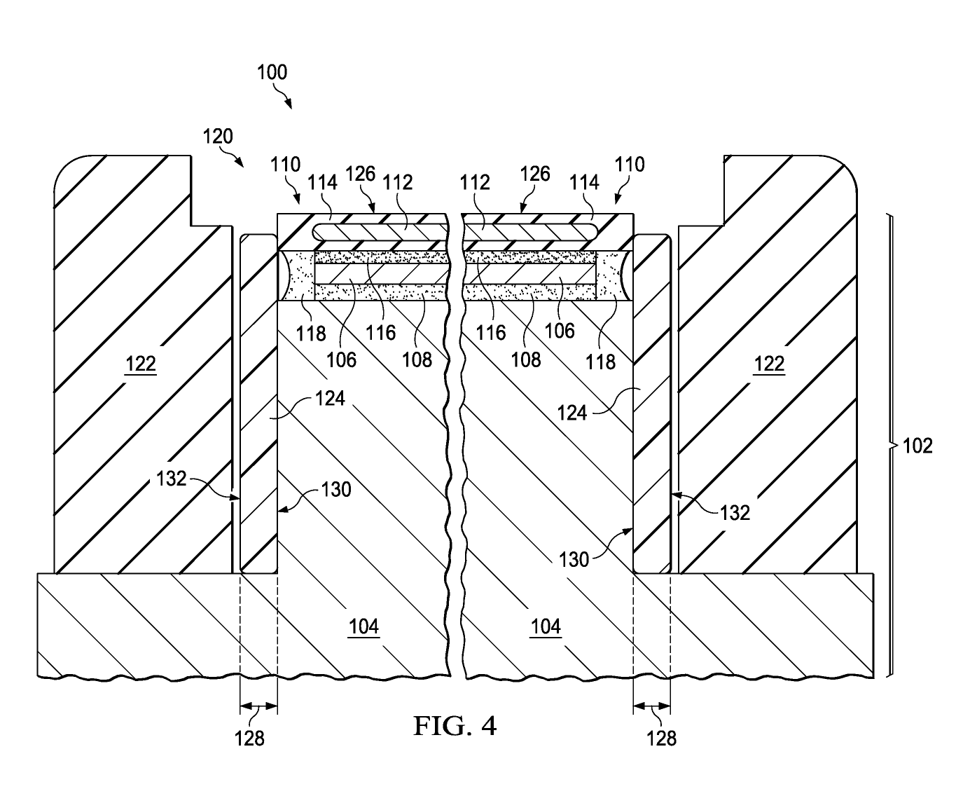

FIG. 4 is a cross section of the plasma etch tool 100 during a chamber cleaning process. The plasma etch tool 100 is free of a semiconductor wafer during the chamber cleaning process. During the chamber cleaning process, the wafer chuck 102 is heated to a process temperature of 50° C. to 200° C. Reactant gases are introduced into the etch region 120 and RF power is applied to the etch region 120 to form a plasma of the reactant gases, so that cleaning of surfaces in the plasma etch tool 100 exposed to the etch region 120 occurs. The plasma etcher chuck band 124 is exposed to reactants from the plasma during the cleaning process.

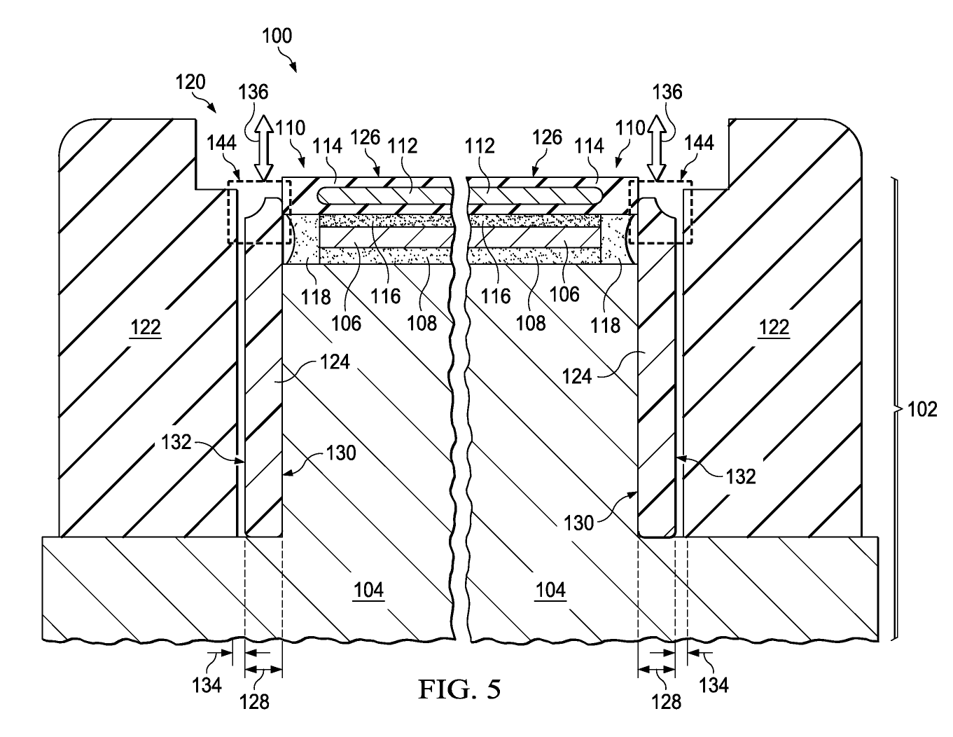

FIG. 5 is a cross section of the plasma etch tool 100 during a maintenance process. The plasma etch tool 100 is free of a semiconductor wafer during the chamber cleaning process. The wafer chuck 102 may be at room temperature during the maintenance process. A top portion 144 of the plasma etcher chuck band 124 is inspected for etch damage, that is removal of material from the plasma etcher chuck band 124, during the maintenance process. An instance of the plasma etcher chuck band 124 with etch damage may be removed and a new instance of the plasma etcher chuck band 124 may be installed during the maintenance process, as indicated by the installation/removal arrows 136. Replacing the plasma etcher chuck band 124 may advantageously prevent etch damage to the polymer material 118, thus reducing maintenance costs for the plasma etch tool 100. As described in reference to FIG. 1, removal and installation of the plasma etcher chuck band 124 with the wafer chuck 102 at room temperature is facilitated by proper selection of the lateral separation 134 between the plasma etcher chuck band 124 and the insulator ring 122.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A plasma etch tool, comprising:
a wafer chuck comprising:
a chuck base;
a functional component layer disposed above the chuck base;
polymer material permanently attached the functional component layer, extending from an end of the functional component layer so as to be exposed; and
a top surface of the wafer chuck suitable for supporting a semiconductor wafer;
a plasma etcher chuck band of elastic polymer disposed around the polymer material, such that:
an inner surface of the plasma etcher chuck band contacts the wafer chuck all along the plasma etcher chuck band; and
the plasma etcher chuck band extends above the polymer material so as to cover the exposed polymer material at the perimeter of the functional component layer; and
an insulator ring disposed around the plasma etcher chuck band, resting on the chuck base, such that an outer surface of the plasma etcher chuck band is separated from the insulator ring.

2. The plasma etch tool of claim 1, wherein the plasma etcher chuck band is formed of a perfluorinated polymer.

3. The plasma etch tool of claim 1, wherein:
the plasma etcher chuck band extends above the polymer material to within 2 millimeters of the top surface of the wafer chuck;
the plasma etcher chuck band extends above the polymer material at least 0.5 millimeters;
a thickness of the plasma etcher chuck band is 1 millimeter to 3 millimeters; and
the outer surface of the plasma etcher chuck band is separated from the insulator ring by a lateral separation of 0.5 millimeters to 1.5 millimeters at room temperature.

4. The plasma etch tool of claim 1, wherein a semiconductor wafer disposed on the top surface of the wafer chuck, in a worst case misalignment configuration, overlaps the outer surface of the plasma etcher chuck band all around the plasma etcher chuck band.

5. The plasma etch tool of claim 1, wherein the functional component layer is a wafer heater.

6. The plasma etch tool of claim 5, wherein the wafer heater is attached to the chuck base by an adhesive layer, and the polymer material isolates the adhesive layer from the etch ambient region.

7. The plasma etch tool of claim 5, wherein the wafer chuck further includes an electrostatic platen disposed above the wafer heater, and the polymer material extends to a perimeter of the electrostatic platen.

8. The plasma etch tool of claim 7, wherein the electrostatic platen is attached to the wafer heater by an adhesive layer, and the polymer material isolates the adhesive layer from the etch ambient region.

9. The plasma etch tool of claim 1, wherein the chuck base contacts the inner surface of the plasma etcher chuck band all along the plasma etcher chuck band when the wafer chuck is heated above 50° C.

10. A method of forming an integrated circuit, comprising the steps of:
heating a wafer chuck in a plasma etch tool to a process temperature of 50° C. to 200° C., the wafer chuck comprising:
a chuck base;
a functional component layer disposed above the chuck base; and
polymer material permanently attached the functional component layer, extending from an end of the functional component layer so as to be exposed;
the plasma etch tool comprising:
a plasma etcher chuck band of elastic polymer disposed around the polymer material, such that:
an inner surface of the plasma etcher chuck band contacts the wafer chuck all along the plasma etcher chuck band ;
the plasma etcher chuck band extends above the polymer material so as to cover the exposed polymer material at the perimeter of the functional component layer; and
the chuck base contacts an inner surface of the plasma etcher chuck band all along the plasma etcher chuck band so that the plasma etcher chuck band isolates the polymer material from an etch ambient region located above the wafer chuck; and
an insulator ring disposed around the plasma etcher chuck band, resting on the chuck base;
placing a semiconductor wafer containing the integrated circuit on the wafer chuck so that a bottom surface of the semiconductor wafer contacts a top surface of the wafer chuck and a top surface of the semiconductor wafer is exposed to the etch ambient region,
introducing reactant gases into the etch ambient region;
forming a plasma in the etch ambient region; and
performing an etch operation on the top surface of the semiconductor wafer.

11. The method of claim 10, further comprising cleaning the plasma etch tool prior to the step of heating the wafer chuck, by a process of:
heating the wafer chuck to a process temperature of 50° C. to 200° C.;
introducing reactant gases into the etch ambient region;
forming a plasma in the etch ambient region; and
performing a chamber cleaning operation, such that the plasma etch tool is kept free of a semiconductor wafer during the chamber cleaning operation.

12. The method of claim 10, further comprising a maintenance operation on the plasma etch tool prior to the step of heating the wafer chuck, by a process of:
maintaining the wafer chuck at room temperature;
removing any semiconductor wafer from the plasma etch tool; and
inspecting a top portion of the plasma etcher chuck band for etch damage.

13. The method of claim 10, further comprising a replacement operation on the plasma etch tool prior to the step of heating the wafer chuck, by a process of:
removing an etch-damaged instance of the plasma etcher chuck band from the plasma etch tool; and
subsequently installing the plasma etcher chuck band in the plasma etch tool.

14. The method of claim 10, wherein the plasma etcher chuck band is formed of a perfluorinated polymer.

15. The method of claim 10, wherein:
the plasma etcher chuck band extends above the polymer material to within 2 millimeters of the top surface of the wafer chuck;
the plasma etcher chuck band extends above the polymer material at least 0.5 millimeters;
a thickness of the plasma etcher chuck band is 1 millimeter to 3 millimeters; and
the outer surface of the plasma etcher chuck band is separated from the insulator ring by a lateral separation of 0.5 millimeters to 1.5 millimeters at room temperature.

16. The method of claim 10, wherein the semiconductor wafer is disposed on the top surface of the wafer chuck in a worst case misalignment configuration, and overlaps the outer surface of the plasma etcher chuck band all around the plasma etcher chuck band.

17. The method of claim 10, wherein the functional component layer is a wafer heater.

18. The method of claim 17, wherein the wafer heater is attached to the chuck base by an adhesive layer, and the polymer material isolates the adhesive layer from the etch ambient region.

19. The method of claim 17, wherein the wafer chuck further includes an electrostatic platen disposed above the wafer heater, and the polymer material extends to a perimeter of the electrostatic platen.

20. The method of claim 19, wherein the electrostatic platen is attached to the wafer heater by an adhesive layer, and the polymer material isolates the adhesive layer from the etch ambient region.
